(19) United States
(12) Patent Application Publication
(10) Pub. No.: US 2015/0090299 A1
(43) Pub. Date: Apr. 2, 2015

(54) PROCESSES AND APPARATUS FOR CLEANING, RINSING, AND DRYING SUBSTRATES

(71) Applicant: Applied Materials, Inc., Santa Clara, CA (US)

(72) Inventors: Brian J. Brown, Palo Alto, CA (US); Ekaterina Mikhaylichenko, San Jose, CA (US); Jonathan Frankel, Los Gatos, CA (US)

(21) Appl. No.: 14/040,571

(22) Filed: Sep. 27, 2013

(51) Int. Cl. H01L 21/02

(52) U.S. Cl. CPC H01L 21/02041
USPC 134/21; 134/95.2

(57) ABSTRACT

In some embodiments, a module is provided that is configured to clean, rinse and dry a substrate. The module includes (1) a tank having an upper tank region positioned above a lower tank region, the upper tank region having (a) an opening through which a substrate is removed from the tank; (b) a first fluid supply configured to supply a first fluid to a surface of a substrate being removed from the tank; and (c) a first suction mechanism, positioned below the first fluid supply, wherein the first suction mechanism is configured to suction fluid supplied from the first fluid supply so as to deter the suctioned fluid from reaching the lower tank region; and (2) a drying vapor supply positioned above the first fluid supply and configured to supply a drying vapor to a surface of a substrate being removed from the tank. Numerous other aspects are provided.

### FIELD

The present application relates to semiconductor device manufacturing. More particularly, the present application relates to processes and apparatus for cleaning, rinsing and drying a semiconductor substrate.

### BACKGROUND

As semiconductor device geometries continue to decrease, the importance of ultra clean processing increases. Aqueous cleaning within a tank of fluid (or a bath) followed by a rinsing bath (e.g., within a separate tank, or by replacing the cleaning tank fluid) may achieve desirable cleaning levels. After removal from the rinsing bath, absent use of a drying apparatus, the bath fluid may evaporate from the substrate's surface causing streaking or spotting, and/or otherwise leaving bath residue on the surface of the substrate. Such streaking, spotting and residue can cause device failure. Accordingly, much attention has been directed to improved methods for drying a substrate as it is removed from an aqueous bath.

A method known as Marangoni drying creates a surface tension gradient to induce bath fluid to flow from the substrate in a manner that leaves the substrate virtually free of bath fluid, and thus avoids streaking, spotting and residue marks. During Marangoni drying a solvent miscible with the bath fluid, such as Isopropyl alcohol (IPA), is introduced to a fluid meniscus which forms as the substrate is lifted from the bath or as the bath fluid is drained past the substrate. The solvent vapor is absorbed along the surface of the fluid, with the concentration of the absorbed vapor being higher at the tip of the meniscus. The higher concentration of absorbed vapor causes surface tension to be lower at the tip of the meniscus than in the bulk of the bath fluid, causing bath fluid to flow from the drying meniscus toward the bulk bath fluid. Such a flow is known as a “Marangoni” flow, and can be employed to achieve substrate drying without leaving streaks, spotting or bath residue on the substrate.

While Marangoni drying is effective at drying a substrate, a continuous need exists for improved methods and apparatuses that quickly and effectively clean, rinse, and dry a substrate.

### SUMMARY

In some embodiments, a module is provided that is configured to clean, rinse and dry a substrate. The module includes (1) a tank having an upper tank region and a lower tank region positioned below the upper tank region, the upper tank region having (a) an opening through which a substrate is removed from the tank; (b) a first fluid supply configured to supply a first fluid to a surface of a substrate as the substrate is removed from the tank; and (c) a first suction mechanism, positioned below the first fluid supply, wherein the first suction mechanism is configured to suction fluid supplied from the first fluid supply so as to deter the suctioned fluid from reaching the lower tank region; and (2) a drying vapor supply positioned above the first fluid supply and configured to supply a drying vapor to a surface of a substrate being removed from the tank.

In some embodiments, a method of creating a two-stage fluid bath for cleaning, rinsing, and drying a substrate is provided. The method includes (1) supplying a cleaning fluid to a first region of a tank so as to create a cleaning fluid bath region; (2) supplying a rinsing fluid to a second region of the tank so as to create a rinsing fluid bath region; (3) supplying suction between the cleaning fluid bath region and the rinsing fluid bath region, to deter cleaning fluid from entering the rinsing fluid bath region; and (4) supplying a drying vapor above the rinsing fluid bath region, so as to dry rinsing fluid from a substrate as the substrate is removed from the rinsing fluid bath region.

In some embodiments, a supply apparatus is provided for coupling to a processing tank having a first width. The supply apparatus includes (1) a first supply face and second supply face that each extend at least the width of a substrate, each of the first and the second supply faces having (a) a first fluid supply configured to supply a first fluid to a surface of a substrate as the substrate is removed from the tank; and (b) a first suction mechanism, positioned below the first fluid supply, wherein the first suction mechanism is configured to suction fluid supplied from the first fluid supply so as to deter the suctioned fluid from reaching a tank region below the supply apparatus; (2) a drying vapor supply positioned above the first fluid supply and configured to supply a drying vapor to a surface of a substrate being removed from the tank; and (3) an opening through which a substrate is removed from the tank, the opening being defined by the first and second supply faces. The first and second supply faces are positioned so as to extend along a front face and a back face of a substrate that is being removed from the tank therethrough, and so as to define a second width that is smaller than the first width of the tank. Numerous other aspects are provided.

Other features and aspects of the present invention will become more fully apparent from the following detailed description, the appended claims and the accompanying drawings.

### BRIEF DESCRIPTION OF THE FIGURES

FIG. 1 is a side elevational view of an apparatus configured to clean, rinse and dry a substrate in accordance with embodiments provided herein;

FIG. 2 is a front view of supply module configured to supply rinsing fluid, drying vapor and suction in accordance with embodiments provided herein; and

FIG. 3 is a flow chart of a method of cleaning, rinsing and drying a substrate in accordance with embodiments provided herein.

### DETAILED DESCRIPTION

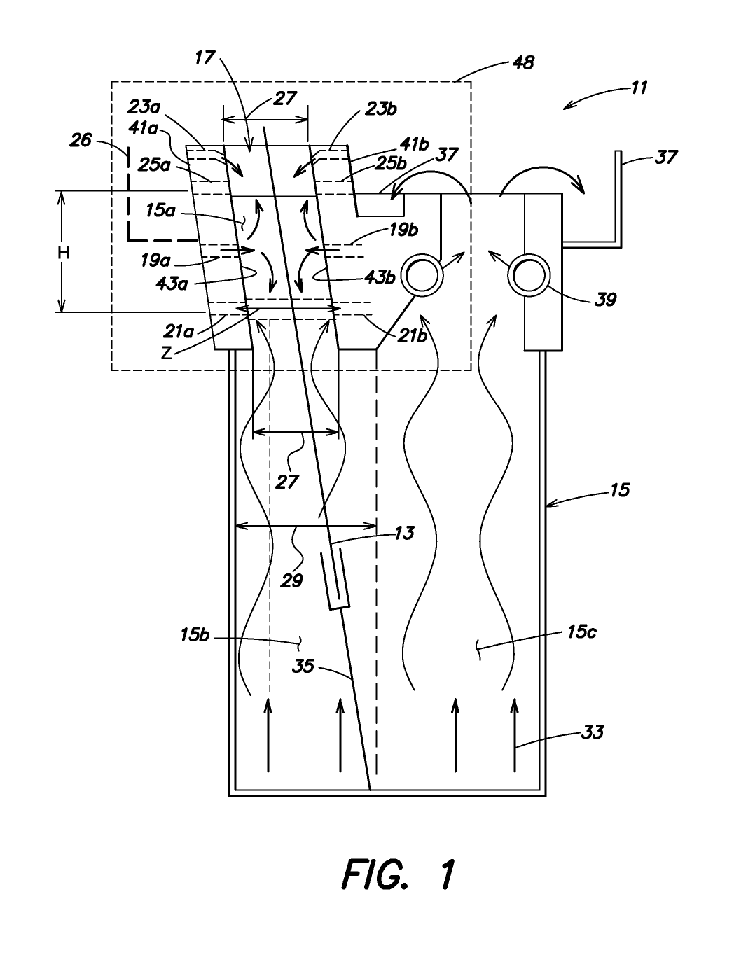

FIG. 1 is a side elevational view of an apparatus 11 configured to clean, rinse and dry a substrate 13. The apparatus 11 comprises a tank 15 having an upper tank region 15a, a lower tank region 15b and an input region 15c, adjacent the upper and lower tank regions 15a, 15b.

The upper tank region 15a has an opening 17 through which the substrate 13 is removed from the tank 15. The upper tank region 15a also has a first fluid supply 19a, 19b configured to supply a first fluid to a surface of the substrate 13. The first fluid supply 19a, 19b may be a fluid inlet, or a nozzle that may spray or jet the first fluid to or toward a surface of the substrate 13. As shown, the first fluid supply 19a, 19b includes a pair of nozzles that direct a rinsing fluid to a front and a back surface of the substrate 13. The rinsing fluid may be, for example, deionized water.

A first suction mechanism 21a, 21b is positioned below the first fluid supply 19a, 19b and may include a pair of suction mechanisms 21a, 21b that provide suction along a front and a back surface of the substrate 13. The suction mechanism may be a vacuum source such as a Venturi pump, liquid ring pump, scroll pump, membrane pump, or the like.

A drying vapor supply 23a, 23b is positioned above the first fluid supply 19a, 19b, and may comprise a drying vapor inlet or a nozzle for directing drying vapor to a front and/or back surface of the substrate 13 as the substrate 13 is removed from the tank 15 via the opening 17 in the upper tank region 15a. The drying vapor may be Isopropyl Alcohol (IPA) or a similar vapor that is miscible with the rinsing fluid supplied via the first fluid supply 19a, 19b and having a surface tension lower than that of the rinsing fluid so as to Marangoni dry the surface of the substrate 13 as the substrate 13 is elevated past the drying vapor supply 23a, 23b.

A second suction mechanism 25a, 25b may be positioned in the upper tank region 15a, above the first fluid supply 19a, 19b and below the drying vapor supply 23a, 23b. As described below, when the apparatus 11 is in operation, a rinsing fluid bath of the first fluid may be created in the upper tank region 15a. The second suction mechanism 25a, 25b may be positioned in the rinsing fluid bath, near a surface of the rinsing fluid bath. The second suction mechanism 25a, 25b may suction rinsing fluid that contains drying vapor, thereby removing drying vapor from the rinsing fluid bath.

Alternatively, the second suction mechanism 25a, 25b may be replaced with an overflow weir 26 (shown in phantom). In such embodiments, the rinsing fluid that contains drying vapor may be removed through the overflow weir 26, and the amount of rinsing liquid flow may be controlled by balancing supply flows from the first fluid supply 19a, 19b and suction flows through the first suction mechanism 21a, 21b.

As shown in FIG. 1, the upper tank region 15a has a width 27 that is smaller than a width 29 of the lower tank region 15b. The smaller width 27 reduces the amount of rinsing fluid and/or suction needed to be supplied by the first fluid supply 19a, 19b and the first suction mechanism 21a, 21b, making it easier to maintain a desired concentration of rinsing fluid in the rinsing fluid bath region and also helping to reduce the amount of rinsing fluid that may pass the first suction mechanism 21a, 21b and enter the lower tank region 15b. In some embodiments, the width 27 of the upper tank region 15a may be about 3 mm to about 20 mm, and in some embodiments about 5 mm to about 10 mm. Other widths may be employed. A partition wall (not shown) also may be provided and function to deter rinsing fluid from the upper tank region 15a from entering the lower tank region 15b.

The lower tank region 15b includes a second fluid supply inlet 33 for supplying a second fluid to the lower tank region 15b. The second fluid may be a different fluid than the first fluid supplied to the upper tank region 15a. For example, the first fluid may be a rinsing fluid such as deionized water and the second fluid may be a cleaning fluid. In some embodiments the cleaning fluid may be a “functional” water such as pH-adjusted water. For example, deionized water may be combined with NH₄OH, TMAH, or another alkali chemistry to increase the pH of the deionized water. This may be useful for cleaning copper surfaces such as CuO and/or particles such as SiO₂, PVA, etc. Other cleaning fluids may be employed.

As stated, the tank 15 may include an input region 15c adjacent the upper and/or lower tank regions 15a and 15b. Having a separate input region allows for faster substrate processing as a first substrate may be cleaned and rinsed within the upper and lower tank regions 15a, 15b while a second substrate is being input to and/or cleaned in the input region 15c. In some embodiments, a rotatable substrate support 35 may be included in the bottom of tank 15 for receiving a substrate in the input region 15c and rotating so as to position the substrate in the lower tank region 15b. A lifting mechanism (not shown) then may lift the substrate from the rotatable substrate support 35 and elevate it through the upper tank region 15a and out of the tank via the opening 17. Suitable rotatable substrate supports and lifting mechanisms are known in the art, such as those employed in Applied Materials' Desica cleaning and rinsing module available from Applied Materials, Inc. of Santa Clara, Calif. Other substrate supports and/or lifting mechanisms may be employed.

In the embodiment of FIG. 1, the input region 15c is in fluid communication with the lower tank region 15b, and the second fluid supply 33 may supply the second fluid to the input region 15c of tank 15 as well as to the lower tank region 15b.

An overflow weir 37 may be positioned along the top of the input region 15c so as to receive an overflow of the second fluid. Additional cleaning nozzles 39 may be positioned in the input region 15c and/or submerged in the cleaning fluid bath (e.g., at a position adjacent a top surface of the cleaning fluid bath). These cleaning fluid nozzles 39 may cause a flow of cleaning fluid that aids removal of particles from the surface of a substrate 13 as the substrate 13 is input to the tank 15 via the input region 15c.

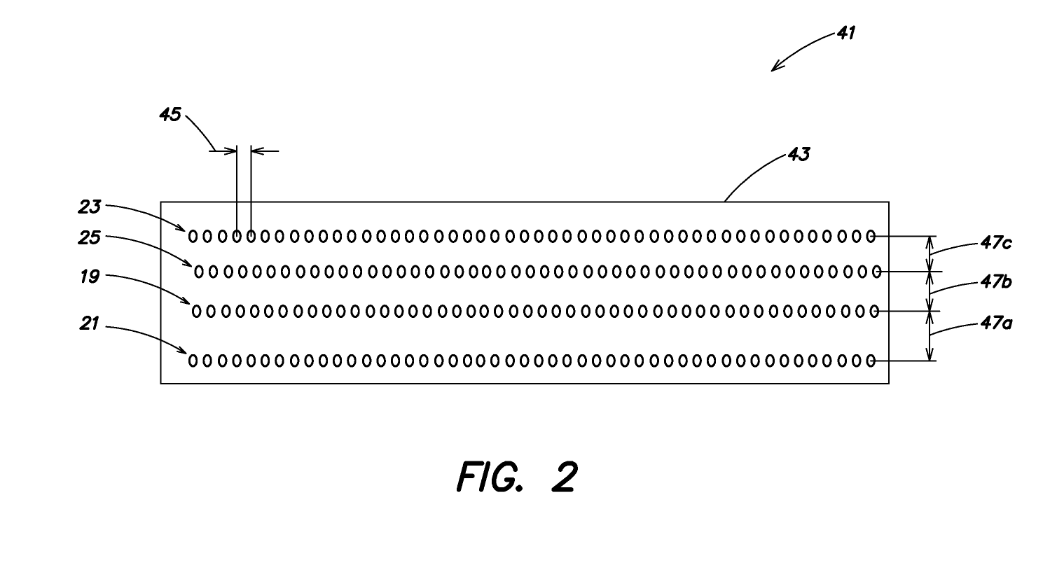

FIG. 2 is a front view of a supply module 41 configured to supply rinsing fluid, drying vapor and suction. The supply module 41 comprises a supply face 43 having the first suction mechanism 21, the first fluid supply 19, the second suction mechanism 25, and the drying vapor supply 23 formed therein. The first suction mechanism 21, the first fluid supply 19, the second suction mechanism 25 and the drying vapor supply 23 may each comprise a plurality of openings having a given spacing 45 between adjacent openings arranged in a line that extends at least as long as the width of the substrate 13 (FIG. 1). For example, in some embodiments the spacing 45 may be about 0.5 mm to about 5 mm. In one or more embodiments, the openings may have a diameter of about 0.05 mm to about 3 mm. Other spacings and/or diameters may be employed.

The distances between the first suction mechanism 21, the first fluid supply 19, the second suction mechanism 25, and the drying vapor supply 23 are indicated by line spacings 47a-c (a line spacing 47a between the first suction mechanism 21 and the first fluid supply 19, a line spacing 47b between the first fluid supply 19 and the second suction mechanism 25, and a line spacing 47c between the second suction mechanism 25 and the drying vapor supply 23). As shown in FIG. 1, in one or more embodiments, the height H of the upper tank region 15a is approximately equal to the distance between the first suction mechanism 21a, 21b and the second suction mechanism 25a, 25b. In some embodiments, the height H may be about 15-30 mm, although other heights may be employed.

In some embodiments, a separate mechanism or module may be employed for one or more of the first suction mechanism 21, the first fluid supply 19, the second suction mechanism 25, and the drying vapor supply 23. For example, a separate bar containing holes for delivering drying vapor may be employed for the drying vapor supply 23.

In an alternative embodiment, the plurality of openings may be replaced with one or more linear openings that extend at least the width of the substrate 13, or with a plurality of linear and standard openings that extend at least the width of the substrate 13 may be employed. Such plurality of openings or such linear openings may function as nozzles through which a chosen flow rate and delivery angle may be achieved. As stated, in some embodiments, the second suction mechanism 25a, 25b may be replaced with an overflow weir. In such embodiments, the rinsing fluid that contains drying vapor may be removed through the overflow weir, and the amount of rinsing liquid flow may be controlled by balancing supply flows from the first fluid supply 19a, 19b and suction flows through the first suction mechanism 21a, 21b. Other suction and/or fluid delivery configurations may be used.

In the embodiment shown in FIG. 1 a pair of the supply modules 41a, 41b, may be mounted to the tank 15, thereby forming a supply apparatus 48 comprised of the pair of supply modules 41a, 41b. The supply modules 41a, 41b are coupled to processing tank 15 so that the first and second supply faces 43a, 43b define the upper tank region 15a and so that the upper tank region 15a has the width 27, which is smaller than the width 29 of the processing tank 15. The pair of supply modules 41a, 41b may also define the opening 17. In this embodiment the first and second supply faces 43a, 43b are positioned so as to extend along a front face and a back face of a substrate that is being removed from the tank 15 through the opening 17. In one embodiment the supply modules 41a, 41b, may be integral with the overflow weir 37 or a portion thereof, such that an existing tank 15 may be easily retrofitted to create the cleaning, rinsing and drying apparatus of the present application.

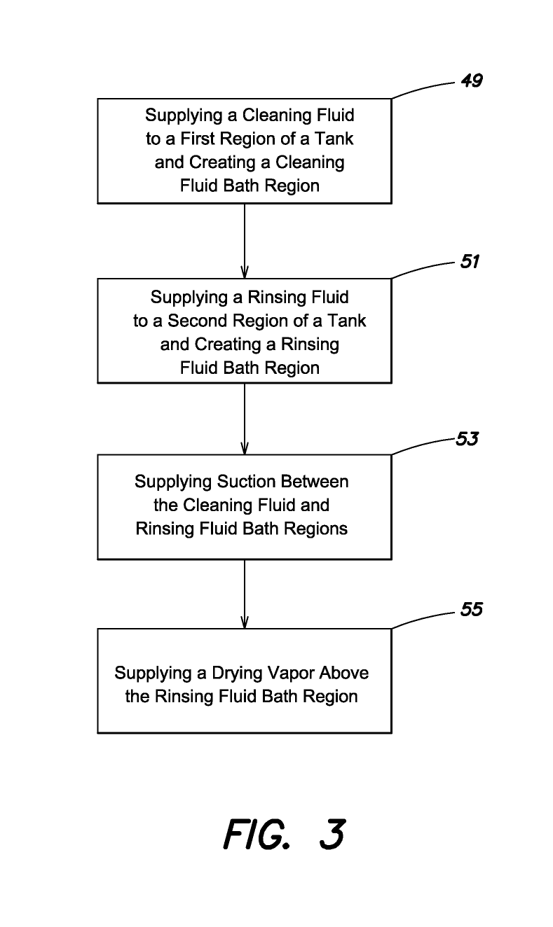

As described further below with reference to FIG. 3 and as shown in FIG. 2, the spacing 45 between openings, the flow rate (delivery or suction), the nozzle angle, and line spacings 47a-c (a line spacing 47a between the first suction mechanism 21 and the first fluid supply 19, a line spacing 47b between the first fluid supply 19 and the second suction mechanism 25, and a line spacing 47c between the second suction mechanism 25 and the drying vapor supply 23) may be selected to achieve a chosen operation.

FIG. 3 is a flow chart of a method of cleaning, rinsing, and drying a substrate in accordance with embodiments provided herein. The method may be performed with the apparatus 11 and the supply module 41 of FIGS. 1 and 2, and is described with joint reference thereto.

In block 49 a cleaning fluid is supplied to a first region of the tank 15, such as the lower tank region 15b and to the input region 15c via the second fluid supply 33, thereby creating a cleaning fluid bath region. In some embodiments, the cleaning fluid may be deionized water combined with NH₄OH, TMAH, or another alkali chemistry to increase the pH of the deionized water. This may be useful for cleaning copper surfaces such as CuO and/or particles such as SiO₂, PVA, etc. Other cleaning fluids may be employed. Once the cleaning fluid level reaches the bottom of the upper tank region 15a, the method proceeds to block 51.

In block 51 a rinsing fluid is supplied to a second region of the tank 15, such as the upper tank region 15a, via the first fluid supply 19, thereby creating a rinsing fluid bath region within the upper tank region 15a. The rinsing fluid may be deionized water, for example, or another suitable rinsing fluid.

In block 53 suction is supplied (via first suction mechanism 21) between the cleaning fluid bath region (lower tank region 15b) and the rinsing fluid bath region (upper tank region 15a). The suction may be applied as soon as the supply of rinsing fluid begins (or before or after the rinsing fluid supply begins). Once the suction is turned on the cleaning fluid may continue to be supplied to the lower tank region 15b and to the input region 15c so that the cleaning fluid level in the input region 15c reaches the top of the input region 15c and begins to overflow into overflow weir 37. The suction rate of the first suction mechanism 21 may be chosen such that the cleaning fluid level is kept below the rinsing region (e.g., below a rinsing fluid bath zone).

By supplying the first suction mechanism 21 below the first fluid supply 19, and above or along the top of the cleaning fluid bath below the rinsing fluid bath, rinsing fluid may be suctioned by the first suction mechanism 21 before it reaches the cleaning fluid bath. Thus, the chosen concentration for the cleaning fluid bath chemistry may be more effectively maintained. Additionally, because the upper tank region 15a has a smaller width than does the lower tank region 15b, a lower flow rate of rinsing fluid may be employed for embodiments that create a rinsing fluid bath in the upper tank region 15a. Such embodiments may reduce fluid consumption cost by reducing rinsing fluid flow. The reduced rinsing fluid flows may reduce the amount of rinsing fluid passing by the first suction mechanism 21 and entering the cleaning fluid bath. Thus a chosen cleaning fluid chemistry concentration may be more easily maintained, and cleaning fluid consumption costs also may be reduced while effective cleaning is achieved. Note that a sufficiently high rinsing fluid rate may be employed to reduce, minimize and/or prevent cross-contamination between the cleaning fluid and rinsing fluid baths, and/or otherwise deter high pH chemicals from entering the rinsing fluid bath (or vice versa).

By supplying suction as the cleaning fluid level begins to reach the upper tank region 15a, cleaning fluid that reaches the first suction mechanism 21 may be suctioned thereby and deterred and/or prevented from entering the upper tank region 15a and the rinsing fluid bath which may be contained therein. In this manner, a chosen concentration/purity of rinsing fluid may be maintained in the rinsing fluid bath region. Particles generated in the cleaning fluid portion of the tank 15 also may be deterred from entering the upper tank region 15a.

The line spacing 47a (FIG. 2) between the first suction mechanism 21 and the first fluid supply 19, (along with the flow/suction rate), nozzle shape, nozzle spacing, nozzle size and the nozzle delivery angle may be adjusted so as to maintain chosen concentrations of cleaning fluid and/or purity of rinsing fluid, and may be selected so as to create/maintain a rinsing fluid bath within the upper tank region 15a. When a rinsing fluid bath is created, the first suction mechanism 21 may suction a mixture of cleaning fluid and rinsing fluid, and the flow rates of the cleaning fluid, the rinsing fluid and the suction rate may be selected such that a chosen transition region may exist between the cleaning fluid bath and the rinsing fluid bath. Within this transition zone (reference numeral Z in FIG. 1) there may be a mixture of the cleaning and the rinsing fluids (e.g., such that a gradient of decreasing cleaning fluid concentration exists in the transition region and such that a region containing essentially no cleaning fluid begins above the transition region). In this manner the cleaning fluid bath and the rinsing fluid bath may be in fluid communication, and a two stage cleaning bath and rinsing fluid bath may be created in a single apparatus, thereby reducing footprint, substrate transfer time and fluid consumption costs and increasing processing speed.

In some embodiments, the rinsing fluid flow rates may be selected to produce a rinsing bath or zone having a height H of about 15-30 mm. Other rinsing fluid heights may be employed. A conductivity sensor (not shown) may be employed to monitor rinsing fluid purity and/or rinse effectiveness. The height of the transition zone Z may depend on such factors as rinsing fluid flow rate, suction rate, cleaning fluid rate, etc. In some embodiments, the transition zone Z may have a height of about 5-10 mm, although other transition zone sizes may be employed. Example rinsing fluid flow rates for deionized water may be about 0.5-2 liters/minute total (e.g., 0.2-1 liter/minute per supply side). In one or more embodiments, approximately 20-50 volume exchanges/minute may be employed for the rinsing fluid bath. Example cleaning fluid flow rates may be about 0.4-4 liters/minute total. In some embodiments, suction rates for the lower suction mechanism 21 may be adjusted to produce about 0.5-5 liters per minute total liquid flow rates (e.g. for combined suction of rinsing and cleaning fluids). In one or more embodiments, the range of flow ratios for rinsing fluid and cleaning fluid through the lower suction mechanism 21 may be between about 1:10 and 10:1, and in some embodiments about 1:1. Other volume exchange rates, fluid flow rates, suction rates and/or fluid flow ratios may be used.

In block 55 a drying vapor (such as IPA) is supplied via the drying vapor supply 23. For example, in some embodiments about 150 standard liters/minute of N₂ with 2-4% IPA may be supplied to a substrate surface during drying. Other flow rates and/or IPA concentrations may be employed.

In the embodiment shown in FIG. 1, a second suction mechanism 25 is positioned below the drying vapor supply 23 (e.g., by a line spacing distance 47c) and is submerged along a top surface of the rinsing fluid bath. In this manner the second suction mechanism 25 may suction rinsing fluid that has drying vapor mixed therein, and deter the drying vapor containing rinsing fluid from altering the concentration of rinsing fluid maintained within the rinsing fluid bath. This may allow a greater surface tension gradient to form as the substrate 13 is lifted from the rinsing fluid bath into the drying vapor. Such a greater surface tension gradient may aid Marangoni drying and create a more repeatable, higher-quality cleaned and dried substrate. The second suction mechanism 25 also may reduce flow stagnation zones at the liquid/air interface in the rinsing fluid zone by replacing free overflow with flow controlled by vacuum suction. Further, the second suction mechanism 25 may facilitate removal of any particles present at the liquid/air interface of the rinsing fluid zone. In some embodiments, the second suction mechanism 25 may be replaced with an overflow weir. In such embodiments, the amount of rinsing liquid flow may be controlled by balancing supply flow from the first fluid supply 19 and suction flow through the first suction mechanism 21.

To conserve drying vapor, in some embodiments, during substrate cleaning, the drying vapor may only be supplied as the substrate 13 begins to be elevated out of the rinsing fluid spray or bath.

In the embodiment shown in FIG. 1, the substrate 13 may be input to the apparatus 11 where it enters the cleaning fluid bath and is cleaned thereby. As the substrate 13 enters the cleaning fluid, submerged cleaning nozzles 39 may direct cleaning fluid to the front and back surfaces of the substrate 13. The substrate may be received on the rotatable substrate support 35 which is positioned to receive the input substrate 13. Thereafter, the rotatable substrate support 35 rotates to position the substrate 13 within the lower tank region 15b, below the upper tank region 15a. The input region 15c and the lower tank region 15b are in fluid communication and both contain cleaning fluid. The substrate 13 therefore continues to be cleaned, and any surface particles from the substrate 13 may enter the cleaning bath fluid.

After the substrate 13 has been cleaned sufficiently, an elevating mechanism (not shown) elevates the substrate 13. As the substrate 13 is elevated it enters the upper tank region 15a; the substrate 13 passes the first suction mechanism 21, which may suction cleaning fluid and may therefore function as an active overflow weir, actively removing cleaning fluid that may have particles that have migrated to the top of the cleaning fluid bath. Further, the first suction mechanism 21 suctions rinsing fluid supplied by the first fluid supply 19, deterring the suctioned rinsing fluid from entering the cleaning fluid in the lower tank region 15b.

In the embodiment shown, the rinsing fluid supply rate, the cleaning fluid supply rate and the suction rate are selected so that a rinsing fluid bath is created in the upper tank region 15a. As the substrate 13 leaves the cleaning fluid bath the substrate 13 passes through a transition region (e.g., adjacent the first suction mechanism 21) wherein the rinsing fluid has diluted the concentration of the cleaning fluid by mixing therewith. The substrate 13 then enters a rinsing fluid bath region where the rinsing fluid concentration/purity is maintained by the first and second suction mechanisms 21 and 25 (and/or the first suction mechanism 21 and an overflow weir in some embodiments). Any cleaning fluid is removed from the substrate 13 in the rinsing fluid bath, and the substrate 13 is elevated from the rinsing fluid bath into a drying vapor region. Within the drying vapor region, a drying vapor is supplied to the surface of the substrate 13 via the drying vapor supply 23 and rinsing fluid is thereby Marangoni dried from the substrate 13.

In one more embodiments, the cleaning fluid may be a functional substrate rinse, such as pH-increased deionized water. With the configuration of the apparatus 11, substrates are treated with cleaning fluid (e.g., pH-adjusted deionized water) for a major portion of residence time in the tank 15. A short, high flow rinsing fluid (e.g., deionized water) rinse in the upper tank region 15a reduces risk of chemical residues remaining on the substrate. Marangoni drying then may be employed as the final drying step.

The foregoing description discloses only example embodiments provided herein. Modifications of the above disclosed apparatus and methods which fall within the scope of the invention will be readily apparent to those of ordinary skill in the art. For example, although the specific embodiment shown in FIG. 1 and described with reference to FIG. 3 employs a rinsing fluid bath, the apparatus 11 may be employed in a manner that sprays rinsing fluid on the substrate 13 to remove cleaning fluid therefrom, instead of submerging the substrate 13 in a rinsing fluid bath. In such an embodiment, the rinsing fluid flow rate provided via the first fluid supply 19, the suction rate supplied by first suction mechanism 21 and/or the cleaning fluid flow rate supplied via the second fluid supply 33 may be adjusted such that a rinsing fluid bath does not form in the upper tank region 15a.

Similarly, the location of the drying vapor supply 23 may be within the upper tank region 15a (with a rinsing fluid bath or rinsing fluid spray below) or may be above the upper tank region. Drying may thus occur within the upper tank region 15a or as the substrate 13 is removed from the upper tank region 15a.

Accordingly, while the present invention has been disclosed in connection with example embodiments thereof, it should be understood that other embodiments may fall within the spirit and scope of the invention, as defined by the following claims.

The invention claimed is:

1. An apparatus adapted to clean, rinse and dry a substrate comprising:
a tank, the tank having an upper tank region, and a lower tank region positioned below the upper tank region, the upper tank region having:
an opening through which a substrate is removed from the tank;
a first fluid supply configured to supply a first fluid to a surface of a substrate as the substrate is removed from the tank; and
a first suction mechanism, positioned below the first fluid supply, wherein the first suction mechanism is configured to suction fluid supplied from the first fluid supply so as to deter the suctioned fluid from reaching the lower tank region; and
a drying vapor supply positioned above the first fluid supply and configured to supply a drying vapor to a surface of a substrate being removed from the tank.

2. The apparatus of claim 1 wherein the first fluid supply and the first suction mechanism are configured to create a first fluid bath in the upper region of the tank such that a substrate being removed from the tank passes through the first fluid bath.

3. The apparatus of claim 2 further comprising a second suction mechanism positioned in the first fluid bath region, above the first fluid supply and below the drying vapor supply, wherein the second suction mechanism is configured to suction, from the first fluid bath, rinsing fluid that contains drying vapor.

4. The apparatus of claim 2 further comprising an overflow weir in the first fluid bath region, above the first fluid supply and below the drying vapor supply, wherein the overflow weir is configured to remove, from the first fluid bath, rinsing fluid that contains drying vapor.

5. The apparatus of claim 1 wherein the upper tank region has a narrower cross section than the lower tank region.

6. The apparatus of claim 1 wherein the fluid supply comprises an underwater nozzle configured to direct the first fluid to the surface of the substrate.

7. The apparatus of claim 1 wherein the lower tank region comprises a second fluid supply inlet for inletting a second fluid, wherein the first fluid is a rinsing fluid and the second fluid is a cleaning fluid.

8. The apparatus of claim 1 wherein the tank further comprises an input region adjacent the upper tank region and the lower tank region for receiving a substrate into the tank.

9. The apparatus of claim 8 wherein:
the lower tank region comprises a second fluid supply inlet;
the input region comprises an overflow weir; and
the first suction mechanism and the second fluid supply inlet are configured so that the first suction mechanism suctions a mixture of the first fluid and the second fluid.

10. The apparatus of claim 1 wherein:
the first fluid supply and the first suction mechanism are configured to create a first fluid bath in the upper region of the tank such that a substrate being removed from the tank passes through the first fluid bath;
the module further comprises a second suction mechanism positioned in the first fluid bath, above the first fluid supply and below the drying vapor supply; and
the second suction mechanism is configured to suction drying vapor from the first fluid bath.

11. The apparatus of claim 10 wherein the upper tank region has a narrower cross section than the lower tank region.

12. The apparatus of claim 10 wherein the fluid supply comprises an underwater nozzle configured to direct the first fluid to the surface of the substrate.

13. The apparatus of claim 10 wherein:
the lower tank region comprises a second fluid supply inlet for inletting a second fluid; and
the first fluid is a rinsing fluid and the second fluid is a cleaning fluid.

14. The apparatus of claim 10 wherein the tank further comprises an input region adjacent the upper tank region and the lower tank region for receiving a substrate into the tank.

15. The apparatus of claim 14 wherein:
the lower tank region comprises a second fluid supply inlet;
the input region comprises an overflow weir; and
the first suction mechanism and the second fluid supply inlet are configured so that the first suction mechanism suctions a mixture of the first fluid and the second fluid.

16. A method of creating a two-stage fluid bath for cleaning, rinsing and drying a substrate, comprising:
supplying a cleaning fluid to a first region of a tank so as to create a cleaning fluid bath region;
supplying a rinsing fluid to a second region of the tank so as to create a rinsing fluid bath region; and
supplying suction between the cleaning fluid bath region and the rinsing fluid bath region, to deter cleaning fluid from entering the rinsing fluid bath region; and
supplying a drying vapor above the rinsing fluid bath region, so as to dry rinsing fluid from a substrate as the substrate is removed from the rinsing fluid bath region.

17. The method of claim 16 wherein the cleaning fluid bath region and the rinsing fluid bath region are in fluid communication such that a transition region that includes cleaning fluid and rinsing fluid, exists between the cleaning fluid bath region and the rinsing fluid bath region.

18. The method of claim 16 further comprising supplying suction along a top surface of the rinsing fluid bath region so as to remove from the rinsing fluid bath, rinsing fluid that contains drying vapor.

19. The method of claim 18 wherein the supplying suction along a top surface of the rinsing fluid bath region comprises submerging a suction mechanism below the top surface of the rinsing fluid bath region, such that a mixture of rinsing fluid and drying vapor is suctioned thereby.

20. The method of claim 16, wherein:
supplying a cleaning fluid to a first region of a tank so as to create a cleaning fluid bath comprises supplying cleaning fluid at a first flow rate;
supplying a rinsing fluid to a second region of the tank so as to create a rinsing fluid bath comprises supplying rinsing fluid at a second flow rate; and
adjusting the first flow rate, second flow rate and the supply of suction so that a desired concentration of cleaning fluid is maintained within the cleaning fluid bath and a desired concentration of rinsing fluid is maintained with in the rinsing fluid bath.

21. A supply system for coupling to a processing tank having a first width, the supply system comprising:
a first and second supply face that each extend at least the width of a substrate, each of the first and the second supply faces having:
a first fluid supply configured to supply a first fluid to a surface of a substrate as the substrate is removed from the tank; and
a first suction mechanism, positioned below the first fluid supply, wherein the first suction mechanism is configured to suction fluid supplied from the first fluid supply so as to deter the suctioned fluid from reaching a tank region below the supply system;
a drying vapor supply positioned above the first fluid supply and configured to supply a drying vapor to a surface of a substrate being removed from the tank; and
an opening through which a substrate is removed from the tank, the opening being defined by the first and second supply faces, wherein the first and second supply faces are positioned so as to extend along a front face and a back face of a substrate that is being removed from the tank there-through, and so as to define a second width that is smaller than the first width of the tank.
